(19) United States
(12) Patent Application Publication
(10) Pub. No.: US 2024/0421033 A1
(43) Pub. Date: Dec. 19, 2024

(54) HEATSINK UNIT, IC SOCKET, SEMICONDUCTOR PACKAGE MAKING METHOD, AND SEMICONDUCTOR PACKAGE

(71) Applicant: YAMAICHI ELECTRONICS CO., LTD., Tokyo (JP)

(72) Inventors: Koichi MIWA, Tokyo (JP); Hideki SAGANO, Tokyo (JP); Masaru SATO, Tokyo (JP)

(21) Appl. No.: 18/270,398

(22) PCT Filed: Dec. 10, 2021
(86) PCT No.: PCT/JP2021/045580

§ 371 Date: Aug. 6, 2024

(30) Foreign Application Priority Data
Jan. 21, 2021 (JP) 2021-007743

(51) Int. Cl. H01L 23/40; H01L 23/043; H01L 23/367

(52) U.S. Cl. CPC H01L 23/4093; H01L 23/043; H01L 23/3672

(57) ABSTRACT

Provided is a heat sink unit that is less likely to damage a package and has excellent handleability. The heat sink unit 1 includes a base 90, a cover 20, a first lever 80, a third lever 50, and a heat sink 30. The first lever 80 is rotatably held by the base 90, carries the heat sink 30 and a heat sink pedestal 40, and is hard stopped at the base 90 by an end portion of the first lever 80. The third lever 50 is rotatably held by the cover 20, is connected to the first lever 80 to open and close the same, and controls up-and-down movements of the heat sink pedestal 40 by a tip end of the third lever 50. The heat sink 30 is configured to press the IC package 100 with timing shifted by a long hole of the third lever 50 after the first lever 80 is hard stopped at the base 90.

### TECHNICAL FIELD

The present invention relates to techniques for assisting the heat dissipation of an IC package during burn-in test.

### BACKGROUND

In a burn-in test of an IC package such as a BGA (ball grid array) device, after the IC package to be tested is accommodated in an IC socket for electrical connection test, an electric signal is sent to the IC package through contact pins of the IC socket from a wiring substrate on which the IC socket is supported and fixed, and various evaluations such as electrical characteristics, durability, and heat resistance are performed. During the burn-in test of the IC package, heat is generated by the power supply to the IC package, so an IC socket and an attachment-type heat sink unit surrounding it may be used together.

As a document disclosing a technique related to this type of heat sink unit, Patent Document 1 can be taken up. The heat sink unit disclosed in Patent Document 1 includes a base frame surrounding the sides of an IC socket, a top frame floatingly supported on the base frame by a coil spring, two arms pivotally supported by drive shafts on the left and right edge walls surrounding the IC socket in the top frame, and two heat sinks supported on the two arms. In this attachment for socket, when each pair of the arm and the heat sink is closed, the bottom of the base portion of the heat sink is in contact with the IC package in the IC socket, the heat of the IC package is transferred from the base portion to a cooling fin, and the heat is dissipated from the cooling fin. In addition, when each pair of the arm and the heat sink is opened, the IC socket in the opening portion of the base frame is exposed upward, and the IC package accommodated in the IC socket can be taken out.

### PRIOR ART REFERENCE

### Patent Document

Patent Document 1: Japanese Patent Publication No. 5095964

### SUMMARY

### Problems to Be Solved

However, the conventional heat sink unit includes one pair or two pairs of heat sinks, and the operation of the heat sinks during opening and closing operations is to move in track on an arc and to operate in contact and non-contact by operating the cover. Therefore, when the heat sink comes into contact with the package, the heat sink tilts and comes into contact with the package from the end portion of the heat sink, causing damage such as scratches or chips to package. In addition, if the operation speed in the process of closing the heat sink from the open state is rapid, the heat sink may damage the upper surface of the semiconductor package due to the impact when the heat sink is closed. In addition, since one pair or more are installed, a plurality of structures for opening and closing the heat sink are required, and the space occupied by the heat sink unit is increased. In addition, since the heat sink is opened in two or more directions in the open state, the directions of access to the socket and the heat sink unit of the device for inserting and removing the package are limited to the upper surface and two directions or less.

The present invention has been made in view of such problems, and one of the objects is to provide a heat sink unit that is less likely to damage a package and has excellent handleability.

### Means for Solving the Problem

In order to solve the above problems, a heat sink unit, which is a preferred embodiment of the present invention, is a heat sink unit that dissipates heat of a package, characterized by including: a base, a cover, a first lever, a third lever, a heat sink, and a heat sink pedestal, wherein the first lever is rotatably held by the base, carries the heat sink and the heat sink pedestal, controls shaking of the heat sink pedestal by a protrusion, and is hard stopped by an end portion of the first lever, the third lever is rotatably held by the cover, is connected to the first lever to open and close the same, and controls up-and-down movements of the heat sink pedestal by a tip end of the third lever, the heat sink is configured to press the package with timing shifted by a long hole of the third lever after the first lever is hard stopped at the base.

In this aspect, the shaking of the heat sink pedestal may be controlled by the protrusion.

In addition, displacement of the first lever may be controlled by the protrusion.

In addition, the third lever may have a connecting portion and a first support portion interlocking with opening/closing operations, and the third lever may be fixed and connected to the first lever with a screw passing through the heat sink and the coil spring.

In addition, the heat sink may be provided with a coil spring.

Further, it may be configured to press the heat sink horizontally against the package while maintaining the heat sink pedestal in a horizontal attitude when the third lever is actuated.

Further, it may be configured to support the heat sink pedestal by a first support portion of the third lever in order to prevent the heat sink from being lowered and vigorously contacting the package due to an impact when the heat sink is closed.

Further, it may be configured to support the heat sink pedestal by the first lever in order to prevent the heat sink from rotating or shaking and contacting the package due to an impact generated during operation of closing the heat sink.

Further, it may be configured to provisionally position a position of the heat sink by the end portion of the first lever and an opening of the cover, and finally position the position of the heat sink by the base during the operation of closing the heat sink.

Further, a second lever rotatably held by the cover may be included, wherein the second lever is connected to the first lever at a tip end portion of the second lever and pressed and fixed to the base, and
the second lever may have a third connecting portion and a fourth connecting portion for pressing and fixing the first lever to the base.

Further, when there is no pressing position in a center of the package, in order to prevent a pressing portion of the heat sink from obliquely contacting a pressing position of the package, a coil spring for balance may be provided above the pressing position inside the heat sink.

Further, a shaft that holds the coil spring for balance may be included, and the heat sink pedestal or the first lever may be provided with a plurality of shaft fixing holes for fixing the shaft.

Further, an end portion of the first lever may be provided with an abutting surface that abuts against a shaft supported by the cover when the first lever is closed to suppress rebound of the first lever, and the first lever may be locked so as to not be opened when the cover reaches the final position after rising.

Further, a torsional coil spring may be provided between the base and the first lever to soften the impact when the first lever is closed.

Further, a coil spring may be provided between the first lever and the base to weaken the rising momentum of the cover and to soften the impact when the first lever is closed.

Further, a coil spring may be provided between the cover and the base to weaken the rising momentum of the cover and to soften the impact when the first lever is closed.

An IC socket, which is another preferred aspect of the present invention, is characterized in that the heat sink unit described above is incorporated in a socket main body of the IC socket.

A manufacturing method of semiconductor package, which is another preferred aspect of the present invention, is characterized by including: a semiconductor assembling process of assembling a semiconductor package by applying an external connection terminal, a protective covering, etc., to a semiconductor element; a first sorting process of sorting out the semiconductor package in which defects are generated by the semiconductor assembling process; a screening process of discriminating good/defective by applying thermal load or electrical load to the semiconductor package which is judged to be a good product through the first sorting process; a second sorting process of sorting out the semiconductor package which is judged to be defective by the screening process; and a shipping process of shipping the semiconductor package which is judged to be a good product by the screening process, wherein in the screening process, an IC socket to which the semiconductor package is detachably attached is mounted on a predetermined circuit board, and the heat sink socket is detachably attached to the IC socket.

A semiconductor package, which is another preferred aspect of the present invention, is manufactured by the manufacturing method described above.

### Effects

According to the present invention, it is possible to provide a heat sink unit that is less likely to damage a package and has excellent handleability.

### BRIEF DESCRIPTION OF DRAWINGS

FIG. 1 (A) is a top view of a heat sink unit 1 according to an embodiment of the present invention, FIG. 1 (B) is a view of (A) viewed from the +Y side, and FIG. 1 (C) is a view of (A) viewed form the −X side;

FIG. 2 is an exploded perspective view of the heat sink unit 1 shown in FIG. 1;

FIG. 3 is a cross-sectional view of FIG. 1 (A) taken along a cutting plane parallel to the XY plane passing between a side plate 22 on the −X side of a cover 20 and a third lever 5;

FIG. 4 (A) is a cross-sectional view showing a state in which the heat sink pedestal 40 is completely lowered, and FIG. 4 (B) is a cross-sectional view showing a state immediately before the heat sink pedestal 40 is completely lowered;

FIG. 5 (A) is a cross-sectional view showing a configuration in which the heat sink pedestal 40 is supported by a first support portion 52 of a third lever 50, and FIG. 5 (B) is an enlarged view within the dashed-dotted line frame of FIG. 5 (A);

FIG. 6 (A) is a diagram showing provisional positioning by the cover 20 and the first lever 80 when the heat sink 30 of the heat sink unit 1 is closed, and FIG. 6 (B) is a diagram showing final positioning by the base 90 and the first lever 80;

FIG. 7 (A) and FIG. 7 (B) are perspective views showing that the second lever 60 has a third connecting portion 65 and a fourth connecting portion 67 for pressing and fixing the first lever 80 to the base 90, and FIG. 7 (C) is a diagram showing how the first lever 80 is pressed and fixed to the base 90 by the second lever 60;

FIG. 8 is a diagram showing an IC socket 111 including an IC package 100 and a test device 500 performing an electrical connection test thereon;

FIG. 9 is a diagram showing the flow of a manufacturing method of IC package 100;

FIG. 10 is a flowchart showing a procedure of a test on an IC package 100;

FIG. 11 (A) is a perspective view showing a configuration in which the heat sink pedestal 40 is supported by the first lever 80, and FIG. 11 (B) is a view of FIG. 11 (A) viewed from the −X side;

FIG. 12 (A) is a diagram showing left rotation of the heat sink 30, and FIG. 12 (B) is a diagram showing right rotation of the heat sink 30;

FIG. 13 (A) is a top view of a heat sink unit 1 according to another embodiment of the present invention, FIG. 13 (B) is a cross-sectional view along line A-A of FIGS. 13 (A), and (C) is a cross-sectional view along line B-B of FIG. 13 (A);

FIG. 14 (A) is a diagram showing that a pressing position 105 of an IC package 100 of a heat sink unit 1 according to another embodiment of the present invention is in the center, and FIG. 14 (B) is a diagram showing that the pressing position 105 of the IC package 100 is displaced;

FIG. 15 (A) is a cross-sectional view showing how a coil spring for balance 802 is installed directly above the pressing position 105 of the heat sink unit 1 according to another embodiment of the present invention to press the pressing position 105 of the IC package 100, and FIG. 15 (B) is a cross-sectional view showing how the coil springs for balance 802 are installed at two locations directly above the pressing position 105 to press the pressing position 105 maintaining balance;

FIG. 16 (A) is a perspective view showing a heat sink pedestal 40 of the heat sink unit 1 according to another embodiment of the present invention, and FIG. 16 (B) is a perspective view showing a first lever 80 of the heat sink unit 1 according to another embodiment of the present invention;

FIG. 17 is a diagram showing how the impact during the first lever 80 being closed is softened by the coil spring 901 between the first lever 80 and the base 90;

FIG. 18 is a diagram showing that how rising momentum of the cover 20 is weakened and the impact during the first lever 80 being closed is softened by the coil spring 902 between the cover 20 and the base 90;

FIG. 19 is a diagram showing how the first lever 80 is closed and locked by the shape of the end portion of the first lever 80 of the heat sink unit 1 according to another embodiment of the present invention; and

FIG. 20 is a diagram showing how the impact during the first lever 80 being closed is softened by the torsional coil spring 905 of the heat sink unit 1 according to another embodiment of the present invention.

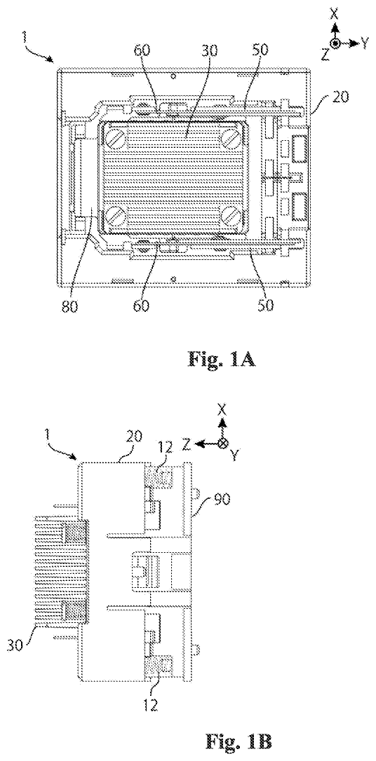

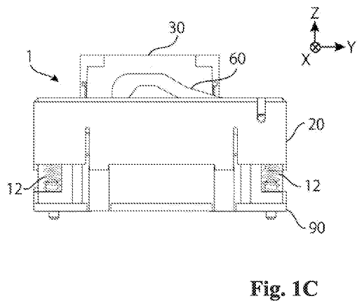

### DETAILED DESCRIPTION

Hereinafter, a heat sink unit 1 according to one embodiment of the present disclosure is explained with reference to drawings. In a burn-in test, the heat sink unit 1 presses the heat sink 30 against a pressing position 105 with an exposed portion of a core of a chip in an IC package 100 (semiconductor package) accommodated in an IC socket 111 as the pressing position 105, and dissipates heat of the IC package 100. The IC socket 111 has a tray portion and a socket main body surrounding the tray portion. In the burn-in test, an IC package 100 to be tested is placed on the tray portion of the IC socket 111, and an electric signal is sent from a substrate on which the IC socket 111 is supported and fixed to the IC package 100 through contact pins of the IC socket 111 to perform various evaluations.

In the following description, the direction in which the IC package 100 is accommodated in the IC socket 111 is appropriately referred to as the Z direction, the direction orthogonal to the Z direction is appropriately referred to as the X direction, and the direction orthogonal to both the Z direction and the X direction is appropriately referred to as the Y direction. In addition, +Z side, which is the open side of the IC socket 111 in the Z direction, may be referred to as the upper side, and the opposite side, the −Z side, may be referred to as the lower side. In addition, the −Y side, which is one side in the Y direction, may be referred to as the front side, and the opposite side, the +Y side, may be referred to as the rear side.

As shown in FIG. 2, the heat sink unit 1 has an E-ring 10, an E-ring 11, a cover 20, four coil springs 12, four screws 13, four coil springs 14, a heat sink 30, two third levers 50, a heat sink pedestal 40, four coil springs 14, two E-rings 15, four coil springs 16, two second levers 60, a first shaft 71, a second shaft 72, a first lever 80, two first support shafts 17, two E-rings 18, two second support shafts 19, and a base 90.

The heat sink 30 has a base portion 34 and a plurality of heat dissipation fins 35 erected from the base portion 34. The base portion 34 is in an approximately rectangular parallelepiped shape. Through holes 31 are provided at the four corners of the base portion 34. In this example, the heat dissipation fin 35 is a plate in parallel to the YZ plane. The plurality of heat dissipation fins 35 are arranged at slight intervals in the X direction. It is to be noted that the shape and the arrangement direction of the heat dissipation fins 35 can be arbitrarily changed according to the specifications.

The cover 20 is in a box shape with the −Z side opened. The cover 20 has a top plate 21 and four side plates 22 extending from the four sides of the top plate 21 to the −Z side. Two of the four side plates 22 face each other in the X direction and the other two side plates 22 face each other in the Y direction. A rectangular opening 24 is provided in the center of the top plate 21. Column portions 23 are provided at the four corners of the lower surface of the top plate 21.

A connecting portion 25 is provided at a position slightly inward from the corner portion where the side on the +Y side and the side on the +Z side of the side plate 22 facing the X direction of the cover 20 intersect. The connecting portion 25 is a round hole. Grooves 26 and 27 recessed toward the connecting portion 25 are provided on the inside and the outside of each of the side plate 22 on the +X side and the side plate 22 on the −X side.

The base 90 is in an approximately rectangular parallelepiped shape. The base 90 has a rectangular opening 94 in the center and four side wall portions 92 surrounding the opening 94. Two of the four side wall portions 92 face each other in the X direction and the other two side wall portions 92 face each other in the Y direction. Two prism portions 93 are provided on the +Y side of the side wall portion 92 on the +Y side.

The base 90 is mounted on the substrate so that the IC socket 111 is housed in the opening 94 and its four sides are surrounded by the side wall portions 92. The four corners of the base 90 are recessed downward as concave portions 99. A column portion 95 is provided on the bottom of the concave portion 99.

A support table portion 96 is provided on the upper surface of the side wall portion 92 of the base 90 on the +Y side. The support table portion 96 is provided with a round hole penetrating the support table portion 96 in the X direction. A receiving table portion 97 is provided on the upper surface of the side wall portion 92 on the −Y side of the base 90. The two end portions of the receiving table portion 97 in the X direction are raised upward higher than the central portion therebetween.

The cover 20 and the base 90 are combined so that coil springs 12 are wound around the column portions 23 of the cover 20 and the column portions 95 of the base 90, and the four side wall portions 92 of the base 90 are covered by the four side plates 22 of the cover 20.

The heat sink pedestal 40 has a dish shape with an approximately the same thickness in the Z direction as that of the top plate 21 of the cover 20. A rectangular opening 44 is provided in the center of the heat sink pedestal 40. Through holes 41 are provided at the four corners of the heat sink pedestal 40. There are convex portions 42 protruding outward at the centers of the lateral side on the +X side and the lateral side on the −X side of the heat sink pedestal 40. The convex portion 42 has a flat plate-like pressing portion 421, an erected portion 422 erected from an outer end portion from the pressing portion 421, and a projecting plate portion 423 projecting inward from the erected portion 422. The pressing portion 421 and the projecting plate portion 423 face each other across a gap.

The first lever 80 has a square frame portion 83, convex portions 831, 832, and 833 vertically bent and extending from two sides of the frame portion 83 facing each other in the X direction, and a convex portion 89 bent and extending from one side that intersects these two sides to the side opposite to the convex portions 831, 832, and 833. A rectangular opening 84 is provided in the center of the frame portion 83. Screw holes 81 are provided at the four corners of the frame portion 83.

The convex portion 832 and convex portion 833 are separated from each other along the extending direction of the frame portion 83. The width of the convex portion 833 is larger than the width of the convex portion 832. The convex portion 832 is provided with a connecting portion 87. The convex portion 833 is provided with a support portion 86. The connecting portion 87 and the support portion 86 are round holes.

The end portion of the convex portion 833 on the side far from the convex portion 832 protrudes to the outside of the first lever 80, and this protruding portion extends around the side opposite to the bent side of the convex portion 833. A connecting portion 85 is provided on the tip end side of the protruding portion of the convex portion 833. The connecting portion 85 is a round hole.

The third lever 50 has a straight advancing portion 51, a tip end portion 52, and a base end portion 53. The tip end portion 52 is a first support portion that supports the heat sink pedestal 40. The tip end portion 52 is housed in a gap between the pressing portion 421 and the projecting plate portion 423 in the heat sink pedestal 40. The base end portion 53 is provided with a connecting portion 55. The connecting portion 55 is a round hole. A support portion 56 is provided at an intermediate portion between the tip end portion 52 and the base end portion 53 in the straight advancing portion 51. The support portion 56 is a long hole.

The second lever 60 has a straight advancing portion 61, a bent portion 62, and a base end portion 63. A connecting portion 67 is provided on the tip end side of the bent portion 62. The base end portion 63 is provided with a connecting portion 65. The connecting portion 67 and the connecting portion 65 are round holes. A support portion 66 is provided at an intermediate portion between the bent portion 62 and the base end portion 63 in the straight advancing portion 61. The support portion 66 is a long hole.

The heat sink pedestal 40 supports the heat sink 30, and the first lever 80 supports the heat sink pedestal 40. The first lever 80 is pivotally supported in the round hole of the support table portion 96 of the base 90 so as to be rockable between a confronting position where the end surface of the base portion 34 of the heat sink 30 on the side opposite to the side of the heat dissipation fin 35 and the IC package 100 confront each other and an open position tilting at 90 degrees with respect to the confronting position.

The heat sink 30, the heat sink pedestal 40, and the first lever 80 are stacked so that the positions of the through hole 31 of the heat sink 30, the through hole 41 of the heat sink pedestal 40, and the screw hole 81 of the first lever 80 are aligned, and the screw 13 is screwed into the screw hole 81 of the first lever 80 through the through hole 31 of the heat sink 30 and the through hole 41 of the heat sink pedestal 40.

A coil spring 14 is provided at a portion of the screw 13 between the head of the screw and the base portion 34 of the heat sink 30, and a coil spring 16 is provided at a portion between the heat sink pedestal 40 and the first lever 80. The base portion 34 of the heat sink 30 passes through the opening 44 of the heat sink pedestal 40 and the opening 84 of the first lever 80 and projects to the side opposite to the side of the heat dissipation fin 35.

The two second levers 60 are inside the convex portions 831, 832, 833 on the +X side and the convex portions 831, 832, 833 on the −X side of the first lever 80. The two third lever 50 are inside the two second levers 60 on the +X side and the −X side. The base end portion 63 of the second lever 60 and the base end portion 53 of the third lever 50 are housed in the groove 26 of the cover 20.

When viewed from the X direction, the positions of the connecting portion 55 of the third lever 50, the connecting portion 65 of the second lever 60, and the connecting portion 25 of the cover 20 are aligned, and the first shaft 71 is passed through them. An E-ring 10 is fixed to the first shaft 71.

The positions of the connecting portion 65 of the second lever 60 and the connecting portion 85 of the first lever 80 are aligned, and the second shaft 72 is passed through them. An E-ring 11 is fixed to the second shaft 72.

The positions of the support portion 66 of the second lever 60 and the support portion 86 of the first lever 80 are aligned, and the first support shaft 17 is fitted to them. An E-ring 15 is fixed to the first support shaft 17.

The positions of the connecting portion 67 of the second lever 60 and the connecting portion 87 of the first lever 80 are aligned, and the second support shaft 19 is fitted to them. An E-ring 18 is fixed to the second support shaft 19.

Here, when the first lever 80 is in the open position, an urging force in a reverse direction to the Z direction is applied to the cover 20 and the base 90 by the coil spring 12 between the cover 20 and the base 90. When the first lever 80 is rocked from the open position toward the confronting position, the coil spring 12 generates a force that lifts up portions of the second lever 60 and the third lever 50 where the first shaft 71 is fitted and pushes the heat sink 30 downward.

More specifically, when the first lever 80 is at the open position, the base end portion 53 of the third lever 50 pushes down the cover 20, and the elastic restoring force of the coil spring 12 sandwiched between the cover 20 and the base 90 is sufficiently large.

When a force is applied from the +Y side to the first lever 80 as well as the heat sink pedestal 40 and the heat sink 30 supported by the first lever 80, the first lever 80 tilts counterclockwise with the second shaft 72 as a fulcrum. In addition, the third lever 50 rotates counterclockwise, and the tip end portion 52 of the third lever 50 approaches the convex portion 42 of the heat sink pedestal 40. When the first support shaft 17 passes a position directly above the first shaft 71 due to the rotation of the third lever 50, the elastic restoring force of the coil spring 12 is released. Due to the extension of the coil spring 12, the cover 20 and the base end portion 53 of the third lever 50 are raised, and the tip end portion 52 of the third lever 50 is lowered.

When the first lever 80 reaches the confronting position, the convex portion 89 of the first lever 80 abuts against the receiving table portion 97 of the base 90. Further tilting of the first lever 80 is restricted by the receiving table portion 97.

After the first lever 80 reaches the confronting position, the base end portion 53 of the third lever 50 is lifted by the force of the coil spring 12, the third lever 50 further rotates with the first shaft 71 as a fulcrum, and the tip end portion 52 of the third lever 50 pushes down the pressing portion 421 of the heat sink pedestal 40. Then, the straight advancing portion 51 of the third lever 50 becomes parallel to the heat sink pedestal 40, and the end surface on the lower side of the base portion 34 of the heat sink 30 contacts the IC package 100 in the IC socket 111.

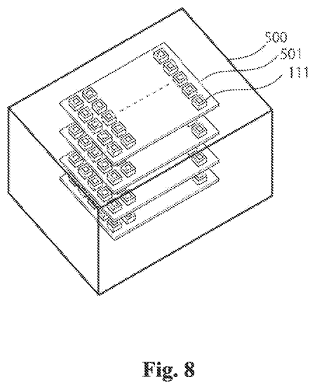

Here, the heat sink unit 1 is incorporated in the socket main body of the IC socket 111 in which the IC package 100 is accommodated. Then, as shown in FIG. 8, a plurality of IC sockets 111 in which the IC package 100 is accommodated are arranged and mounted on a predetermined circuit board 501 of a test device 500, and the test device 500 performs an electrical connection test of the IC package 100 in each IC socket 111.

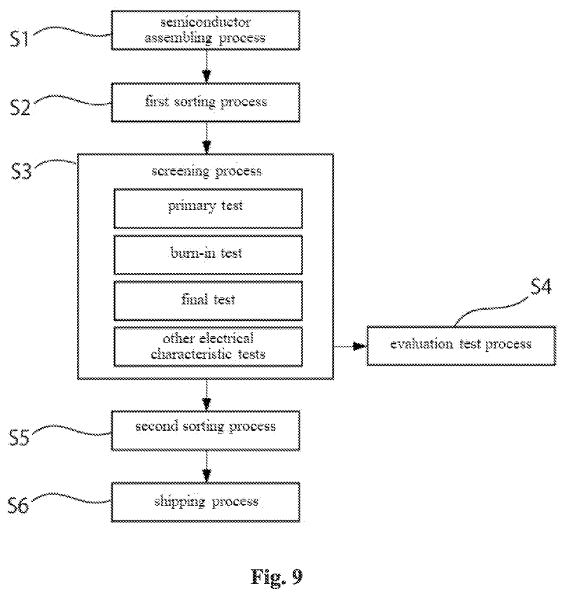

FIG. 9 is a diagram showing the procedure of a manufacturing method of IC package 100. The manufacturing method of IC package 100 includes a semiconductor assembling process S1, a first sorting process S2, a screening process S3, an evaluation test process S4, a second sorting process S5, and a shipping process S6. In the semiconductor assembling process S1, an IC package 100 is assembled by applying an external connection terminal, a protective covering, etc., to a semiconductor element. In the first sorting process S2, an IC package 100 in which defects are generated by the semiconductor assembling process S1 is sorted out. In the screening process S3, good/defective is discriminated by applying a thermal load or an electrical load to the IC package 100 judged to be a good product through the first sorting process S2. In the screening process S3, a primary test, a burn-in test, a final test, and other electrical characteristic tests are performed. In addition, the IC socket 111 is attached on the circuit board 501, the IC package 100 is attached to the IC socket 111, and the heat sink unit 1 is attached to the IC package 100. In the shipping process S6, the IC package 100 judged to be a good product by the screening process S3 is shipped.

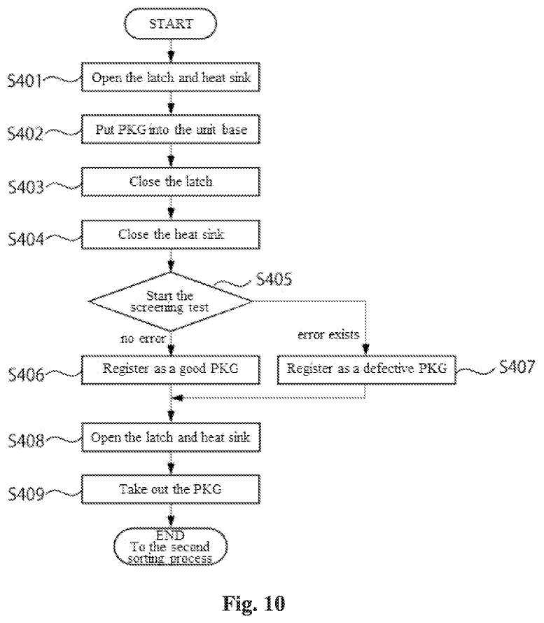

FIG. 10 is a flowchart showing the procedure of the evaluation test process S4. In step S401 of FIG. 10, the latch and the heat sink 30 are opened. In the next step S402, the IC package 100 is put into the base 90. In the next step S403, the latch is closed. In the next step S404, the heat sink 30 is closed.

In the next step S405, the screening test is started. If there is no error in this test, the process proceeds to step S406; if there is an error, the process proceeds to step S407. In step S406, it is registered as a good package. In step S407, it is registered as a defective package. After that, the process proceeds to step S408.

In step S408, the latch and the heat sink 30 are opened. In the next step S409, the IC package 100 is taken out. All the processing is completed by the above, and it proceeds to the second sorting process S5.

The above is the details of the present embodiment. The heat sink unit 1 according to the present embodiment includes a base 90, a cover 20, a first lever 80, a third lever 50, and a heat sink 30. The first lever 80 is rotatably held by the base 90 and carries the heat sink 30 and the heat sink pedestal 40. Shaking of the heat sink pedestal 40 is controlled by raised portions at both ends in the X direction of the receiving table portion 97 of the base 90 which are protrusions, and the end portion of the first lever 80 is hard stopped at the base 90. The third lever 50 is rotatably held by the cover 20 and connected to the first lever 80 to open and close the same. The up-and-down movement of the heat sink pedestal 40 is controlled by the tip end of the third lever 50. After the first lever 80 is hard stopped at the base 90, the heat sink 30 presses the IC package 100 with the timing shifted by the long hole of the third lever 50. Therefore, it is possible to provide a heat sink unit 1 that is less likely to damage an IC package 100 and has excellent handleability.

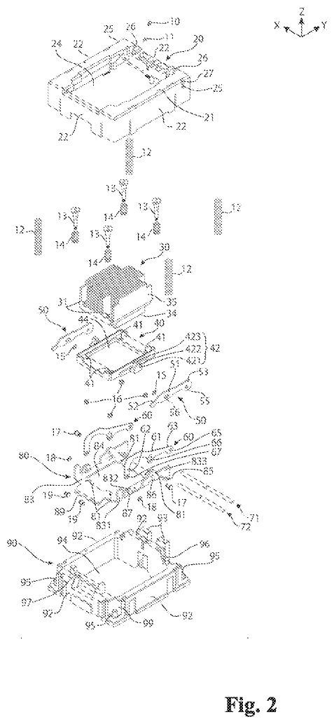

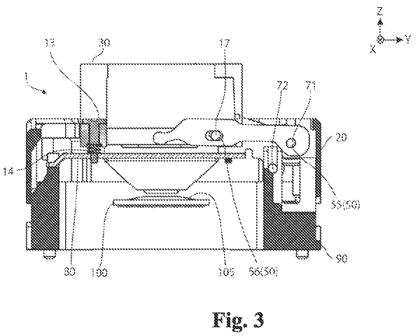

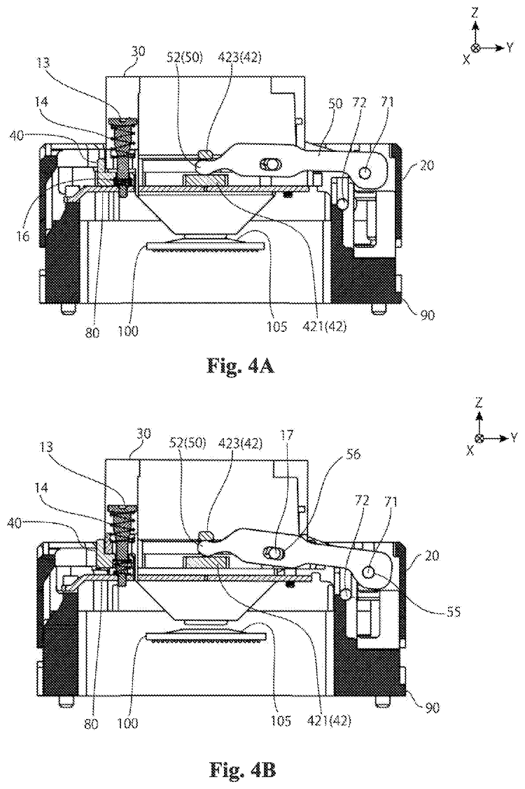

In addition, in the heat sink unit 1 according to the present embodiment, as shown in FIG. 3, the third lever 50 has a connecting portion 55 and a first support portion 52 interlocking with opening/closing operations, and the third lever 50 is fixed and connected to the first lever 80 with a screw 13 passing through the heat sink 30 and the coil spring 12. In addition, as shown in FIG. 4, the heat sink 30 is provided with a coil spring 14. Therefore, when the cover 20 is closed, the impact applied to the heat sink 30 is absorbed, the attitude of the heat sink pedestal 40 is maintained horizontally, and the pressing force to the IC package 100 can be freely set by setting the load of the coil spring 14.

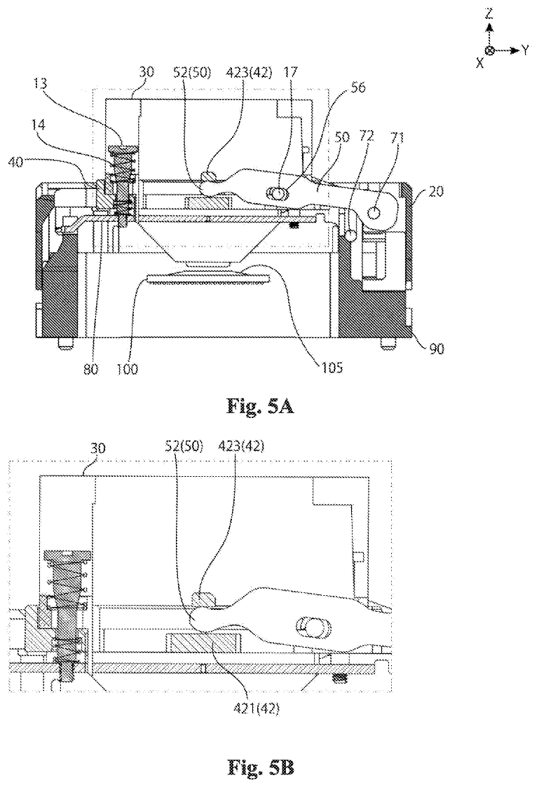

In addition, in the heat sink unit 1 according to the present embodiment, as shown in FIG. 5, the heat sink pedestal 40 is supported by the tip end portion 52, which is the first support portion of the third lever 50. Therefore, it is possible to prevent the heat sink 30 from lowering due to the impact when the heat sink 30 is closed and contacting the IC package 100 vigorously.

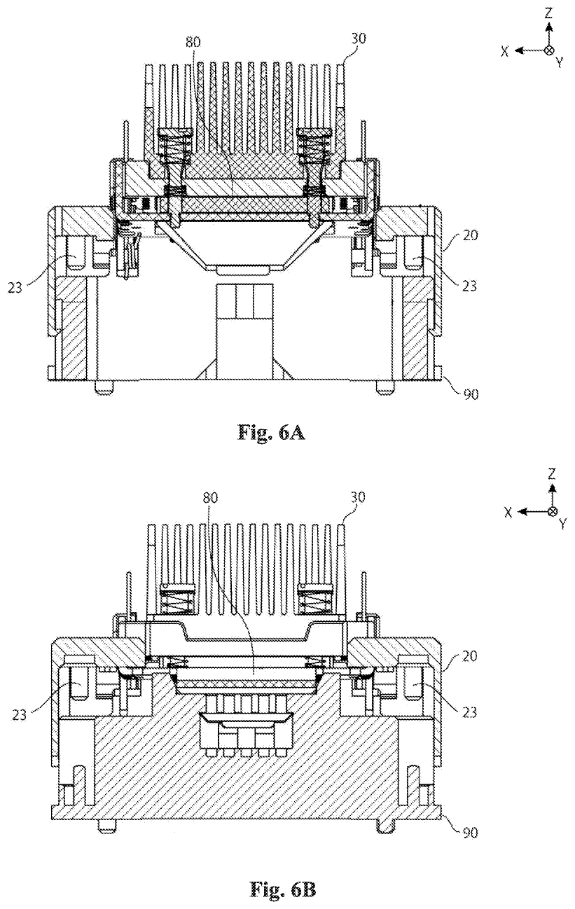

In addition, in the heat sink unit 1 according to the present embodiment, as shown in FIG. 6, when the heat sink 30 is closed, the position of the heat sink 30 is provisionally positioned by the convex portion 89, which is the tip end portion of the first lever 80, and the opening 24 of the cover 20, and the position of the heat sink 30 is finally positioned by the base 90. Therefore, when the heat sink 30 is closed, the position of the heat sink 30 is provisionally positioned by the mechanism of the shape near the tip end portion of the first lever 80 and the shape of the opening 24 of the cover 20.

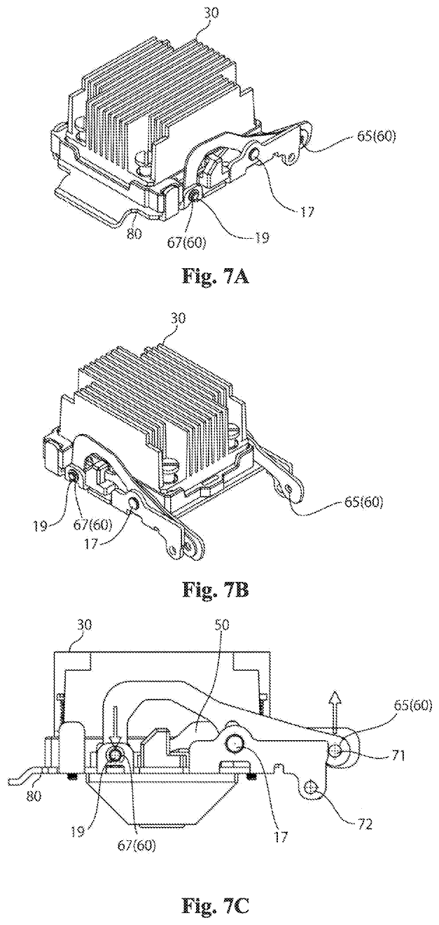

In addition, in the heat sink unit 1 according to the present embodiment, as shown in FIG. 7, the second lever 60 rotatably held by the cover 20 is connected to the first lever 80 at its tip end portion, is pressed against and fixed to the base 90, and has a third connecting portion 65 and a fourth connecting portion 67 for pressing and fixing the first lever 80 to the base 90. By adding the second lever 60 having the connecting portion 65, the connecting portion 67, and the support portion 66, the first lever 80 can be reliably pressed against and fixed to the base 90.

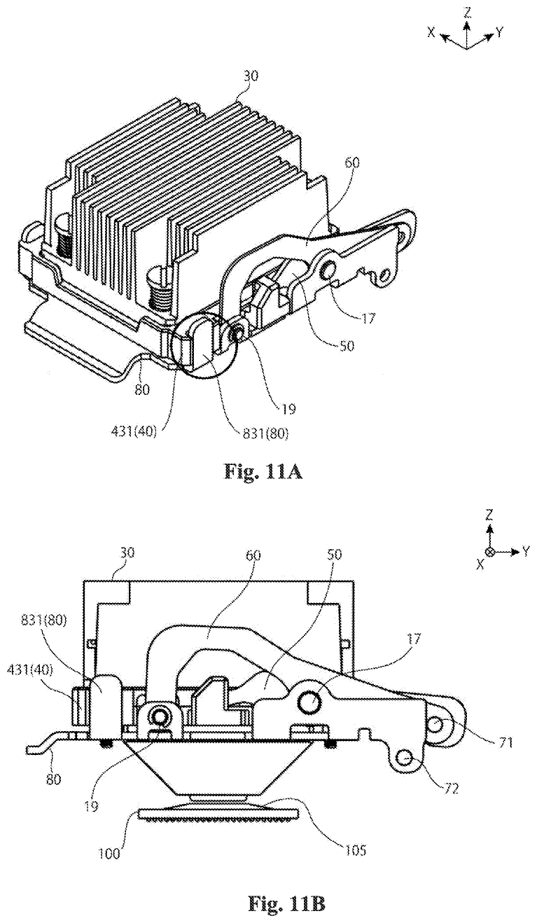

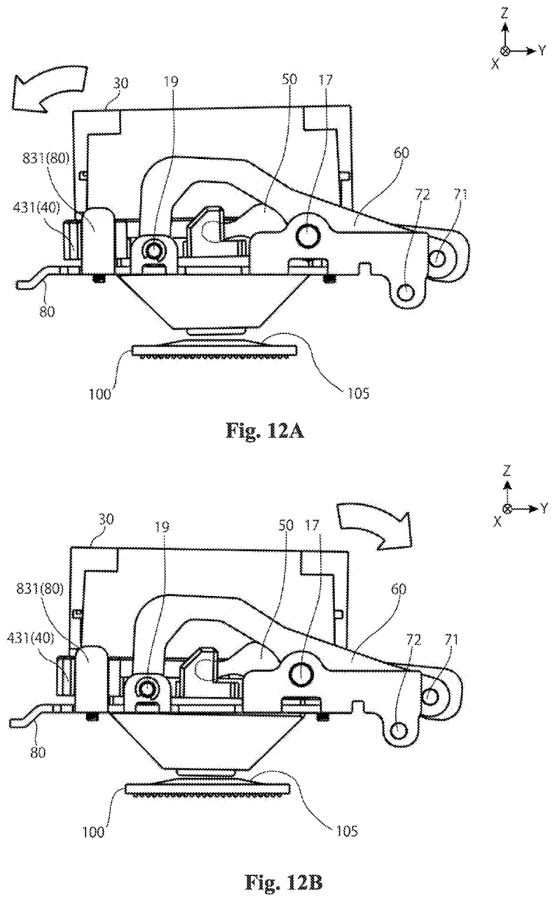

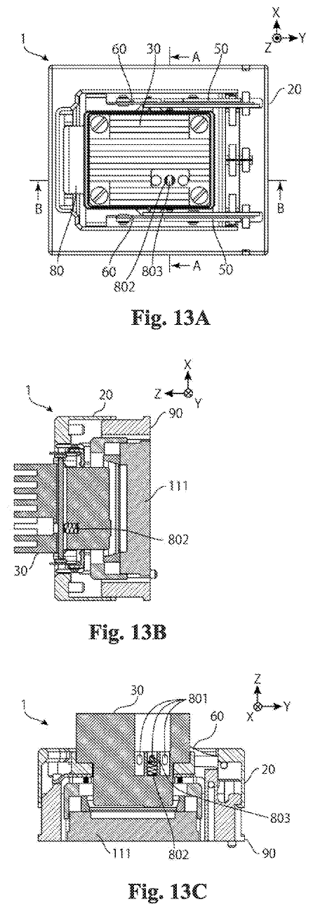

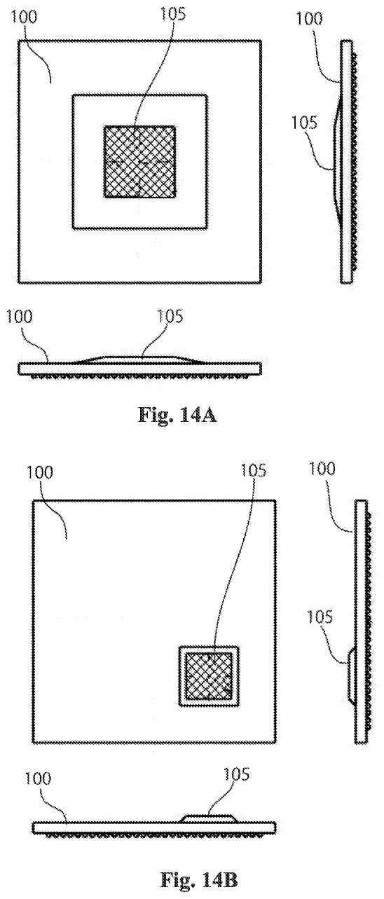

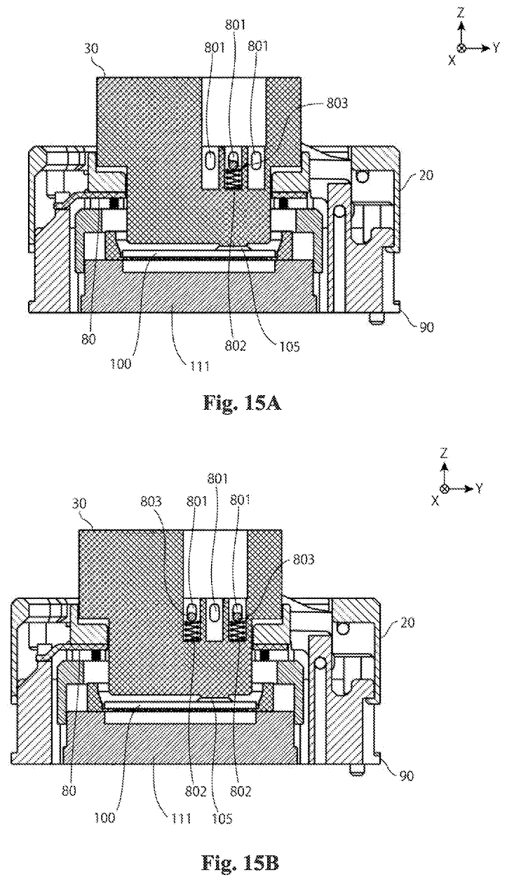

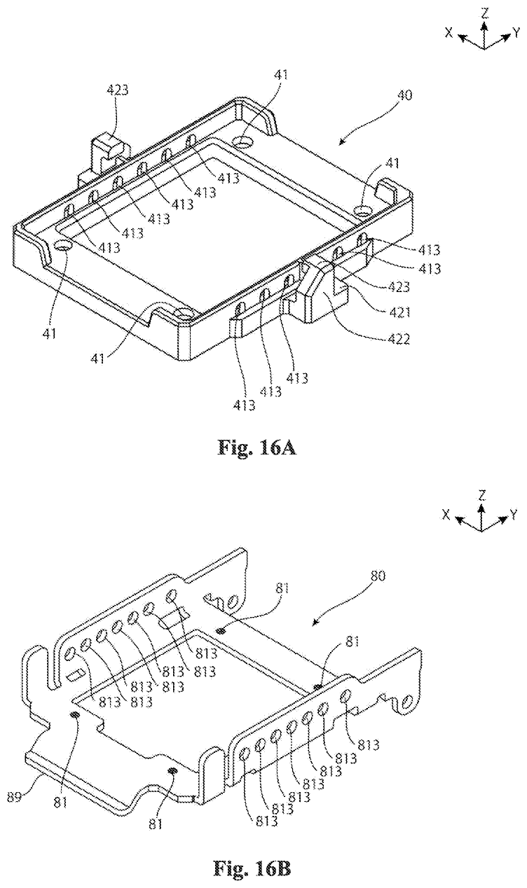

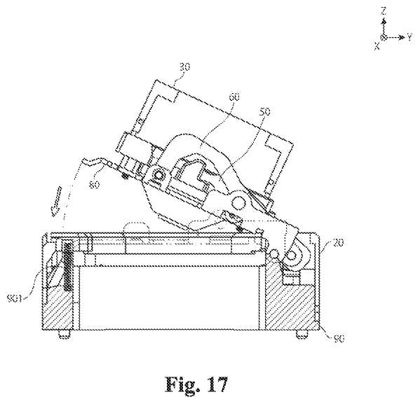

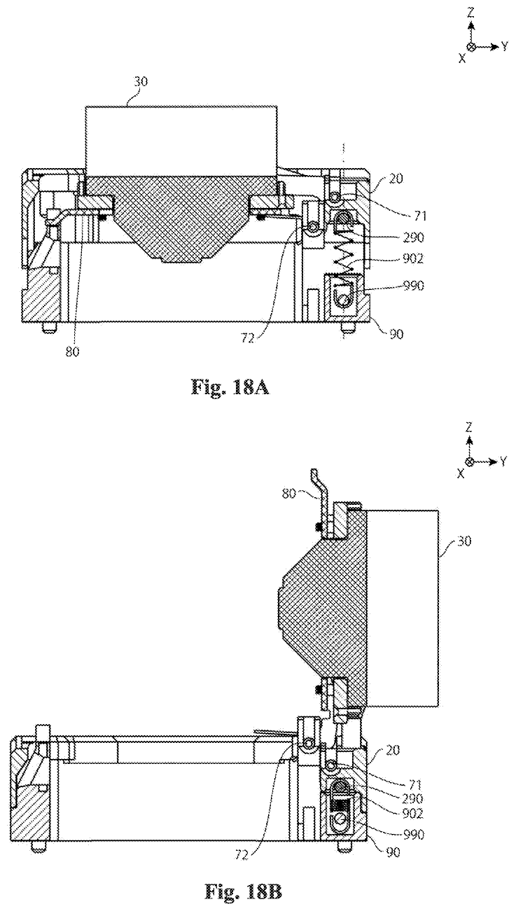

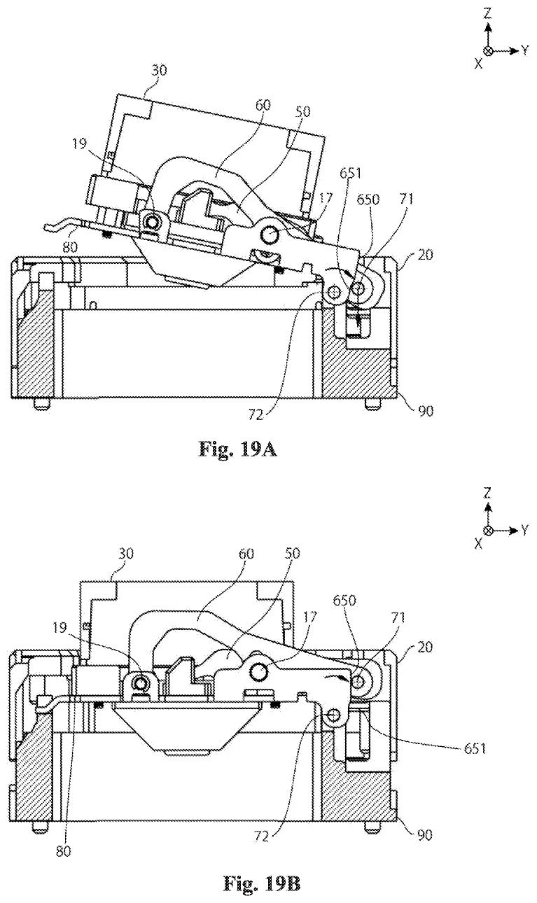

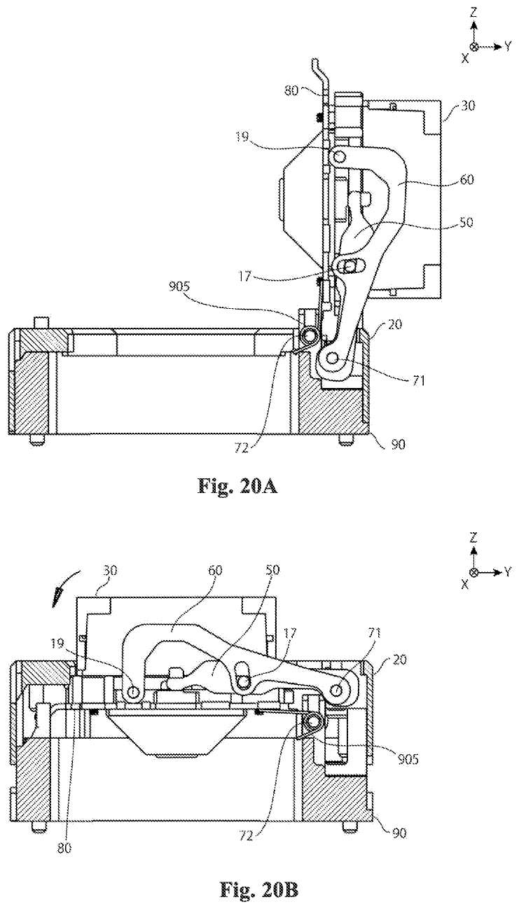

Although one embodiment of the present invention has been described above, the following modifications may be added to this embodiment.
(1) In the above embodiment, as shown in the circle frame of FIG. 11 (A), holding portions 431 for supporting the convex portions 831 of the first levers 80 may be provided on the side surface on the +X side and the side surface on the −X side of the heat sink pedestal 40, a heat sink suppressing mechanism may be formed by the convex portions 831 and the holding portions 431, and the heat sink pedestal 40 may be supported by the first lever 80. According to this heat sink suppressing mechanism, the heat sink 30 can be prevented from rotating or shaking and coming into contact with the IC package 100 when it is rotated to the left as shown in FIG. 12 (A) or rotated to the right as shown in FIG. 12 (B).
(2) In the above embodiment, as shown in FIG. 13 (A), FIG. 13 (B), and FIG. 13 (C), a coil spring for balance 802 may be provided above the pressing position 105 in the heat sink 30. Here, in the IC package 100, as shown in FIG. 14 (A), the pressing position 105 may be in the center, and as shown in FIG. 14 (B), the pressing position 105 may be displaced from the center. As shown in FIG. 15 (A), the heat sink 30 may be provided with a plurality of grooves and a plurality of holes 801 passing through above the plurality of grooves in the heat sink in the X direction, the groove directly above the pressing position 105 may be provided with a coil spring for balance 802, a shaft 803 may be passed through the hole 801 of the groove, and the pressing position 105 may be pressed by the elastic force of the coil spring for balance 802. In addition, as shown in FIG. 15 (B), two coil springs for balance 802 may be set in grooves at two places on the +Y side and the −Y side directly above the pressing position 105, shafts 803 may be passed through the holes 801 of these two grooves, and the pressing position 105 may be pressed while balancing the two coil springs for balance 802. In addition, in this case, as shown in FIG. 16 (A), the heat sink pedestal 40 may be provided with a plurality of shaft fixing holes 413 for fixing the shafts 803, and as shown in FIG. 16 (B), the first lever 80 may be provided with a plurality of shaft fixing holes 813 for fixing the shafts 803. According to the configuration of this embodiment, when there is no pressing position 105 in the center of the IC package 100, the pressing portion of the heat sink 30 can be prevented from obliquely contacting the pressing position 105 of the IC package 100.
(4) In the above embodiment, as shown in FIG. 17, a coil spring 901 may be provided between the first lever 80 and the base 90. According to this configuration, it is possible to weaken the rising momentum of the cover 20 and to soften the impact when the first lever 80 is closed.
(5) In the above embodiment, as shown in FIG. 18 (A) and FIG. 18 (B), a coil spring 902 having hooks at both ends fixed to a horizontal bar 290 of the cover 20 and a horizontal bar 990 of the base 90 may be provided between the cover 20 and the base 90. According to this configuration, it is possible to soften the impact when the first lever 80 is closed.
(6) In the above embodiment, as shown in FIG. 19 (A) and FIG. 19 (B), the end portion of the first lever 80 may be provided with an abutting surface 650 that abuts against the first shaft 71 supported by the cover 20 to suppress rebound the first lever 80 when the first lever 80 is closed, and the first lever 80 may be locked so as not to be opened when the cover 20 reaches the final position after rising. In this case, it is more preferable to provide a curved surface 651 inwardly curved below the abutting surface 650.
(7) In the above embodiment, as shown in FIG. 20 (A) and FIG. 20 (B), a torsional coil spring 905 may be provided between the base 90 and the first lever 80. According to this configuration, it is possible to soften the impact when the first lever 80 is closed.
(8) In the above embodiment, the third lever 50 is rotatably held by the cover 20 and is connected to the first lever 80 to open and close the same, and the up-and-down movements of the heat sink pedestal 40 were controlled by the tip end of the third lever 50. However, the up-and-down movements of the heat sink pedestal 40 may be controlled by a portion other than the tip end of the third lever 50.
(9) In the above embodiment, shaking of the heat sink pedestal 40 was controlled by the raised portions at both ends in the X direction of the receiving table portion 97 of the base 90, which are protrusions. However, after the convex portion 831 of the first lever 80 (FIG. 11 (A) and FIG. 11 (B)) is housed between the left and right inner edges of the cover 20 and provisionally positioned by the first lever 80 and the cover 20, the displacement of the first lever 80 in the X direction may be controlled by housing the convex portion 89 of the first lever 80 between the left and right raised portions of the receiving table portion 97 of the base 90 and positioning it by the first lever 80 and the protrusions of the base 90.
(10) In the above embodiment, the left and right edges of the convex portion 89 of the first lever 80 are extended in the −Z side as protruding portions, and the receiving table portion 97 of the base 90 is surrounded by the left and right protruding portions, and positioning is performed by the first lever 80 and the base 90, thereby the displacement of the first lever 80 in the X direction may be controlled.
(11) In the above embodiment, the first lever 80 is hard stopped at the base 90 by the convex portion 89, which is its tip end. However, it may be hard stopped at the base 90 by an end portion other than the convex portion 89 of the first lever 80 (for example, a flange provided in the lateral direction of the first lever 80).

### EXPLANATION OF REFERENCE SYMBOLS

1 heat sink unit
11 ring
12 coil spring
14 coil spring
15 ring
16 coil spring
17 first support shaft
18 ring
19 second support shaft
20 cover
21 top plate
22 side plate
23 column portion
24 opening
25 connecting portion
26 groove
30 heat sink
31 through hole
34 base portion
35 heat dissipation fin
40 heat sink pedestal
41 through hole
42 convex portion
44 opening
50 third lever
51 straight advancing portion
52 tip end portion
53 base end portion
55 connecting portion
56 supporting portion
60 second lever
61 straight advancing portion
62 bent portion
63 base end portion
65 third connecting portion
66 supporting portion
67 fourth connecting portion
71 first shaft
72 second shaft
80 first lever
81 hole
83 frame portion
84 opening
85 connecting portion
86 supporting portion
87 connecting portion
89 convex portion
90 base
92 side wall portion
93 prism portion
94 opening
95 column portion
96 support table portion
97 table portion
99 concave portion
100 package
105 pressing position
111 socket
290 horizontal bar
431 holding portion
413 shaft fixing hole
421 pressing portion
422 erected portion
423 projecting plate portion
500 test device
501 circuit board
650 abutting surface
651 curved surface
801 hole
802 coil spring for balance
803 shaft
813 shaft fixing hole
831 convex portion
832 convex portion
833 convex portion
901 coil spring
902 coil spring
905 coil spring
990 horizontal bar

What is claimed is:

1. A heat sink unit that dissipates heat of a package, comprising a base, a cover, a first lever, a third lever, a heat sink, and a heat sink pedestal, wherein
the first lever is rotatably held by the base, carries the heat sink and the heat sink pedestal, and is hard stopped at the base by an end portion of the first lever,
the third lever is rotatably held by the cover, is connected to the first lever to open and close the same, and controls up-and-down movements of the heat sink pedestal by a tip end of the third lever, and
the heat sink is configured to press the package with timing shifted by a long hole of the third lever after the first lever is hard stopped at the base.

2. The heat sink unit according to claim 1, wherein
shaking of the heat sink pedestal is controlled by a protrusion.

3. The heat sink unit according to claim 1, wherein
displacement of the first lever is controlled by a protrusion.

4. The heat sink unit according to any one of claims 1 to 3, wherein
the third lever has a connecting portion and a first support portion interlocking with opening/closing operations, and
the third lever is fixed and connected to the first lever with a screw passing through the heat sink and a coil spring.

5. The heat sink unit according to claim 4, wherein
the heat sink is provided with a coil spring.

6. The heat sink unit according to claim 5, wherein
the heat sink unit is configured to press the heat sink horizontally against the package while maintaining the heat sink pedestal in a horizontal attitude when the third lever is actuated.

7. The heat sink unit according to claim 6, wherein
the heat sink unit is configured to support the heat sink pedestal by a first support portion of the third lever in order to prevent the heat sink from being lowered and vigorously contacting the package due to an impact when the heat sink is closed.

8. The heat sink unit according to claim 7, wherein
the heat sink unit is configured to support the heat sink pedestal by the first lever in order to prevent the heat sink from rotating or shaking and contacting the package due to an impact generated during operation of closing the heat sink.

9. The heat sink unit according to claim 8, wherein
the heat sink unit is configured to provisionally position a position of the heat sink by the end portion of the first lever and an opening of the cover, and finally position the position of the heat sink by the base during the operation of closing the heat sink.

10. The heat sink unit according to claim 9, comprising a second lever rotatably held by the cover, wherein the second lever is connected to the first lever at a tip end portion of the second lever and pressed and fixed to the base, wherein
the second lever has a third connecting portion and a fourth connecting portion for pressing and fixing the first lever to the base.

11. The heat sink unit according to claim 8, wherein
when there is no pressing position in a center of the package, in order to prevent a pressing portion of the heat sink from obliquely contacting a pressing position of the package, a coil spring for balance is provided above the pressing position inside the heat sink.

12. The heat sink unit according to claim 11, comprising a shaft that holds the coil spring for balance, wherein
the heat sink pedestal or the first lever is provided with a plurality of shaft fixing holes for fixing the shaft.

13. The heat sink unit according to claim 12, wherein
an end portion of the first lever is provided with an abutting surface that abuts against a shaft supported by the cover when the first lever is closed to suppress rebound of the first lever, and the first lever is locked so as to not be opened when the cover reaches the final position after rising.

14. The heat sink unit according to claim 13, wherein
a torsional coil spring is provided between the base and the first lever to soften the impact when the first lever is closed.

15. The heat sink unit according to claim 10, wherein
a coil spring is provided between the first lever and the base to weaken the rising momentum of the cover and to soften the impact when the first lever is closed.

16. The heat sink unit according to claim 15, wherein
a coil spring is provided between the cover and the base to weaken the rising momentum of the cover and to soften the impact when the first lever is closed.

17. An IC socket, wherein a heat sink unit according to any one of claims 1 to 16 is incorporated in a socket main body of the IC socket.

18. A manufacturing method of semiconductor package, comprising:
a semiconductor assembling process of assembling a semiconductor package by applying an external connection terminal, a protective covering, etc., to a semiconductor element;
a first sorting process of sorting out the semiconductor package in which defects are generated by the semiconductor assembling process;
a screening process of discriminating good/defective by applying thermal load or electrical load to the semiconductor package judged to be a good product through the first sorting process;
a second sorting process of sorting out the semiconductor package which is judged to be defective by the screening process; and
a shipping process of shipping the semiconductor package which is judged to be a good product by the screening process, wherein
in the screening process, an IC socket to which the semiconductor package is detachably attached is mounted on a predetermined circuit board, and the heat sink socket according to claim 1 is detachably attached to the IC socket.

19. A semiconductor package manufactured by the manufacturing method of semiconductor package according to claim 18.
